(19) United States
(12) Patent Application Publication
(10) Pub. No.: US 2007/0240979 A1
(43) Pub. Date: Oct. 18, 2007

(54) Shield Body and Vacuum Processing Apparatus

(75) Inventors: Toshihisa Nozawa, Amagasaki-shi (JP); Tamaki Yuasa, Amagasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/577,198

(22) PCT Filed: Sep. 27, 2005
(86) PCT No.: PCT/JP05/17778

§ 371 Date: Apr. 13, 2007

(30) Foreign Application Priority Data
Oct. 13, 2004 (JP) 2004-298966

(51) Int. Cl. C23C 14/00

(52) U.S. Cl. 204/298.01

(57) ABSTRACT

A vacuum processing apparatus using a shield member that is used in a processing chamber of the vacuum processing apparatus, that has a heating unit and that has a simple structure enabling the shield member to be thinned. A vacuum processing apparatus having a processing chamber, a gas exhaust unit for discharging gas in processing space inside the processing chamber, a support base for holding a substrate to be processed, and a shield member placed inside the processing chamber. The shield member has an outer wall structure exposed to the processing space that is located inside the processing chamber and is reduced in pressure, inner space formed inside the outer wall structure and isolated from the processing space, and a heating unit placed in the inner space and heating the outer wall structure. The inner space is communicated with the outside of the vacuum processing chamber, and the heating unit is constructed so as to extend into the inner space in a sheet-like form.

### FIELD OF THE INVENTION

The present invention relates to a shield member for use in a vacuum processing apparatus and a vacuum processing apparatus using the shield member.

### BACKGROUND OF THE INVENTION

Conventionally, in the manufacture of, e.g., semiconductor devices, display devices and electronic devices, use has been made of various kinds of so-called vacuum processing apparatuses that perform processing of a target substrate, such as film formation, etching, surface treatment and the like, in an atmosphere of vacuum state or depressurized state.

In case of using these vacuum processing apparatuses, debris scattered during the process of film formation, etching, surface treatment or the like adhere to an inner wall surface of a processing chamber in which the target substrate is held. In this case, the debris may be turned to a deposit which in turn is peeled off in the form of particles, thus becoming a cause of contaminating the target substrate.

In order to prevent the debris from adhering to the inner wall surface of the processing chamber, there has been used a so-called shield plate for covering debris-depositing portions within the processing chamber, including the inner wall surface of the processing chamber.

In case such a shield plate is provided inside the processing chamber of the vacuum processing apparatus, generation of particles can be avoided by replacing the shield plate with a new one or removing the debris deposited on the shield plate during the course of maintenance. This helps to save maintenance costs and shorten a maintenance time, as compared with a case where the debris are deposited on the processing chamber and the like.

However, in the event that the shield plate is arranged within the processing chamber of the vacuum processing apparatus, the shield plate is expanded or contracted in accordance with a temperature variation in the processing chamber during the course of, e.g., film formation, etching and surface treatment. This may sometimes cause the deposit adhering to the shield plate to be peeled off from the shield plate, thus creating particles. Furthermore, since the temperature of the shield plate may sometimes affect the substrate processing, it is desirable to make the temperature of the shield plate controllable.

Taking this into account, there has been a case where a heating unit, e g., a heater is added to a shield plate in a processing chamber to heat the shield plate (see, Japanese Patent Laid-open Publication No. 2000-082699).

However, addition of the heater to the shield plate provided within a processing chamber of a vacuum processing apparatus may cause various problems as follows.

For example, in case of attaching a heater to an outside of a shield plate, the heater is required to withstand a vacuum or depressurized state developed within a processing chamber. Accordingly, a limited kind of material is usable as the heater, which may often impose a restriction on the heater in terms of its kind structure material or the like.

Furthermore, the shield plate carrying the heater comes to have a complicated and large-sized structure, so that the shield plate becomes thickened. Also, the cost of the shield plate including the heater may be increased.

### SUMMARY OF THE INVENTION

It is, therefore, an object of the present invention to provide a novel and useful shield member for use in a vacuum processing apparatus that can eliminate the problems noted above and a vacuum processing apparatus using the shield member.

More specifically, the present invention provides a structurally simple and thin shield member having a heating unit, which is usable within a processing chamber of a vacuum processing apparatus, and a vacuum processing apparatus using the shield member.

In accordance with a first aspect of the present invention, there is provided a shield member provided in a processing chamber of a vacuum processing apparatus, the shield member including: an outer wall structure exposed to a depressurized processing space in the processing chamber, the outer wall structure having an inner space isolated from the processing space; and a heating unit provided within the inner space for heating the outer wall structure, wherein the inner space communicates with an outside of the processing chamber and the heating unit is formed into a sheet shape to extend through the inner space.

In accordance with a second aspect of the present invention, there is provided a vacuum processing apparatus including: a gas exhaust unit for evacuating a processing space in a processing chamber; a support base for supporting a target substrate; and a shield member provided in the processing chamber, the shield member comprising: an outer wall structure exposed to the processing space within the processing chamber, the outer wall structure having an inner space isolated from the processing space; and a heating unit provided within the inner space for heating the outer wall structure, wherein the inner space communicates with an outside of the processing chamber and the heating unit is formed into a sheet shape to extend through the inner space.

In accordance with the present invention, it becomes possible to provide a structurally simple and thin shield member having a heating unit, which is usable within a processing chamber of a vacuum processing apparatus, and a vacuum processing apparatus using the shield member.

### BRIEF DESCRIPTION OF THE DRAWINGS

FIG. 1 is a schematic view showing a vacuum processing apparatus in accordance with a first embodiment of the present invention.

FIG. 2 is a perspective view schematically illustrating a shield member employed in the vacuum processing apparatus shown in FIG. 1.

FIG. 3 shows a first modified embodiment of the vacuum processing apparatus shown in FIG. 1.

FIG. 4 shows a second modified embodiment of the vacuum processing apparatus shown in FIG. 1.

FIG. 5 shows a third modified embodiment of the vacuum processing apparatus shown in FIG. 1.

FIG. 6 shows a fourth modified embodiment of the vacuum processing apparatus shown in FIG. 1.

FIG. 7 is a view illustrating a radiation plate used in the vacuum processing apparatus shown in FIG. 6.

### DETAILED DESCRIPTION OF THE PREFERRED EMBODIMENTS

Hereinafter, preferred embodiments of the present invention will be described in detail with reference to the accompanying drawings.

### First Embodiment

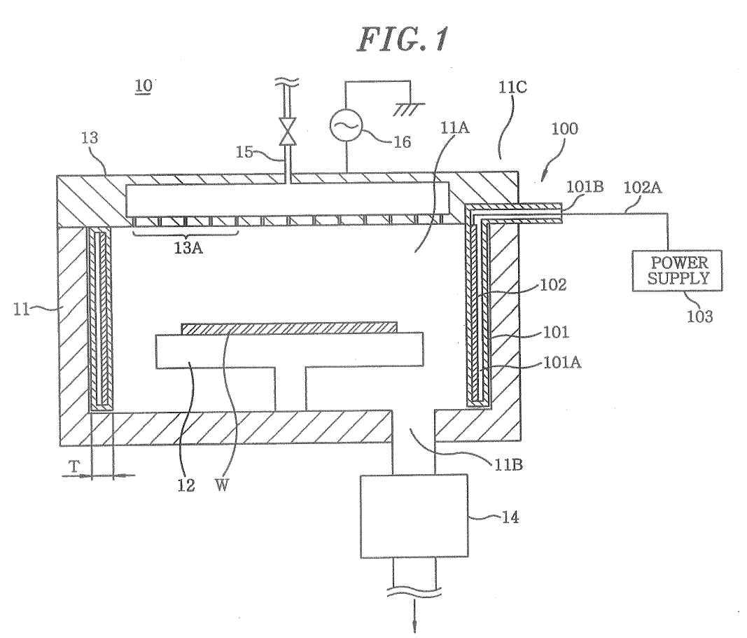

FIG. 1 schematically shows a vacuum processing apparatus 10 in accordance with a first embodiment of the present invention and a shield member 100 employed in the vacuum processing apparatus 10.

Referring to FIG. 1 the vacuum processing apparatus 10 includes a generally cylindrical processing chamber 11 having, e.g., a top opening, and a supply section 13 having, e.g., a so-called shower head structure, the supply section 13 being provided on the processing chamber 11 to close off the opening of the processing chamber 11.

A processing space 11A is defined by the processing chamber 11 and the supply section 13. At a bottom portion of the processing space 11A within the processing chamber 11, there is provided a support base 12 for supporting a target substrate W, e.g., a semiconductor wafer. The support base 12 may be configured to have a heating unit, e g., a heater.

A gas exhaust unit 14 e.g., a vacuum pump, is connected to a gas exhaust port 11B of the bottom portion of the processing chamber 11. The gas exhaust unit 14 is capable of evacuating the processing space 11A to a vacuum state. The term “vacuum state” used herein refers to not only a vacuum state in a strict sense but also what is called a depressurized state, i.e., a state in which the processing space is evacuated by the vacuum pump but contains a residual material, e g., a residual gas.

A supply line 15 is connected to the supply section 13, and a processing gas required to perform a substrate processing such as film formation, etching, surface treatment or the like is supplied from the supply line 15 to be introduced into the processing space 11A through a plurality of gas inlet holes 13A formed in the supply section 13.

Further a high frequency power supply 16 is electrically connected to the supply section 13 to apply a high frequency power thereto, thereby generating plasma to activate processing gas in the processing space 11A. This provides a so-called capacitively coupled plasma generating unit.

With the vacuum processing apparatus 10 of the present embodiment, a shield member 100 for protecting an inner wall surface of the processing chamber 11 is installed within the processing space 11A. The shield member 100 serves to prevent debris scattered during the substrate processing such as film formation, etching and surface treatment, from adhering to the inner wall surface of the processing chamber 11. Thus, generation of particles can be avoided by replacing the shield member with a new one or separating the shield member from the processing chamber to remove the debris deposited on the shield member during the course of maintenance. This helps to save maintenance costs and shorten a maintenance time, as compared with a case where the debris are deposited on the processing chamber and the like.

In the present embodiment, the shield member 100 has an outer wall structure 101 exposed to the processing space 11A, an inner space 101A defined in the outer wall structure 101 and isolated from the processing space 11A, and a heating unit 102 provided in the inner space 101A for heating the outer wall structure 101. The inner space 101A communicates with an outside of the processing space 11A and the heating unit 102 extends within the inner space 101A in a sheet-like shape.

Thus, the shield member 100 of the present embodiment has a simple structure with the heating unit. Furthermore, the shield member 100 having therein the heating unit is formed in a thin and compact structure by reducing the thickness of the outer wall structure thereof.

Moreover, the inner space 101A is in communication with the exterior of the processing chamber 11, i.e., an outer space 11C extending outside the processing space 11A. In this case, the inner space 101A communicates with the outer space 11C via an opening 101B of the outer wall structure 101 opened toward the outer space 11C. Since the outer space 11C is filled with the air and kept in an atmospheric pressure, the inner space 101A is also filled with the air and comes to have the atmospheric pressure. That is to say, the inner space 101A is isolated from the processing space 11A by the outer wall structure 101 on the side of the processing space 11A and communicates with the outer space 110 via the opening 101B on the side of the outer space 11C, thus kept in the atmospheric pressure.

Thanks to this fact, the heating unit 102, e.g., a heater, provided in the inner space 101A, is isolated from a vacuum environment and can be used in an atmospheric pressure state. For example, conventionally, a heating unit is attached to a shield plate in a vacuum environment, the heating unit is subject to various restrictions in terms of a material thereof. For example, the shape and size of the heating unit is restricted in terms of its characteristics, e.g., a gas emission characteristic. In accordance with the present embodiment, the material of the heating unit is less restricted than that of the conventional one in terms of a gas emission characteristic and enjoys an increased design flexibility. This makes it possible to manufacture the heating unit with various kinds of materials in a variety of shapes thereby providing an advantageous effect that the heating unit can be easily formed into a simple, thin and small-sized shape in a cost-effective manner.

Thus, it becomes possible to use a rubber heater, a polyimide resin heater, a mica sheet heater and the like, which are difficult to use in the vacuum state. This makes it possible to manufacture, e.g., a heating unit extending in a sheet-like shape within the inner space 101A in a cost-effective manner and in a simple structure.

Thanks to the features noted above, the shield member of the present embodiment can be formed into a thin shape. As shown in FIG. 1, the shield member, i.e., the outer wall structure 101 having the heating unit 102 provided within the inner space 101A, can be made to have a thickness T of 5 mm or less. In this regard, there is no need for the outer wall structure 101 to have a uniform thickness over the entire region thereof. It will be sufficient if major portions of the outer wall structure 101 exposed to the processing space 11A have a thickness of T, 5 mm or less in the present embodiment.

Further, a power supply 103 for supplying an electric power to the heating unit 102 is provided in the outer space 11C. A connecting line 102A extends from the heating unit 102 to the power supply 103 through the opening 101B to thereby connect the heating unit 102 to the power supply 103. In the case where the heating unit 102 is connected to the power supply 103 provided in the outer space 11C as described above, it is easy to connect the heating unit to external equipments including the power supply because the inner space 101A remains in communication with the outer space 11C. In this case, it is possible to readily connect the heating unit to the external equipments including the power supply in a simple manner without requiring, e.g., a sealing material, a gap-filling material, a flange and so forth.

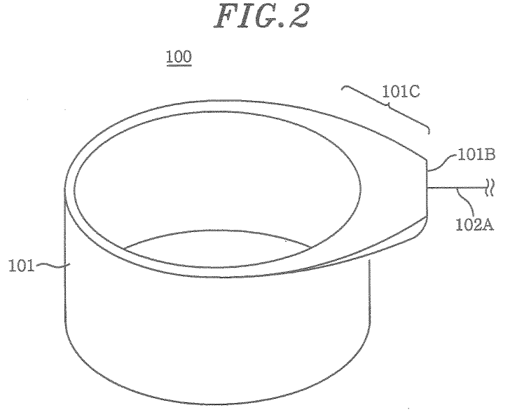

Next, FIG. 2 schematically illustrates a perspective view of the shield member 100 shown in FIG. 1. Like parts are designated by like reference numerals in the drawings and redundant descriptions on the parts that have been described above will be omitted.

Referring to FIG. 2, the shield member 100 has a generally cylindrical shape and is of a structure that the heating unit of, e g., sheet-like shape extends along the inner space formed within the generally cylindrical outer wall structure 101. Furthermore, the shield member 100 is provided with, e.g., a visor-like connection portion 101C extending radially outwardly from a peripheral edge of the cylindrical outer wall structure. The opening 101B is formed at a leading end of the connection portion 101C and the connecting line 102A is inserted through the opening 101B.

As can be seen from FIGS. 1 and 2, the shield member 100 of generally cylindrical shape is formed along the inner wall surface of the processing chamber 11 to surround the support base 12, thereby preventing any debris from adhering to the inner wall surface of the processing chamber 11. The structure of the shield member is not limited to the shape illustrated in FIGS. 1 and 2 but may be modified or changed depending on the shape of the processing chamber and the kinds of processing apparatuses. For example, the shield member may be formed into a rectangular shape to conform to a generally rectangular processing chamber. Furthermore, the shield member may be divided into plural parts to match the inner wall surface of the processing chamber. The attachment position of the shield member is not limited to the inner wall surface of the processing chamber. Alternatively, the shield member may be configured to cover structural objects in the processing chamber, e.g., the support base or the gas supply section such as the shower head and the like, thereby avoiding any formation of an attaching material or a deposit on the structural objects.

### Second Embodiment

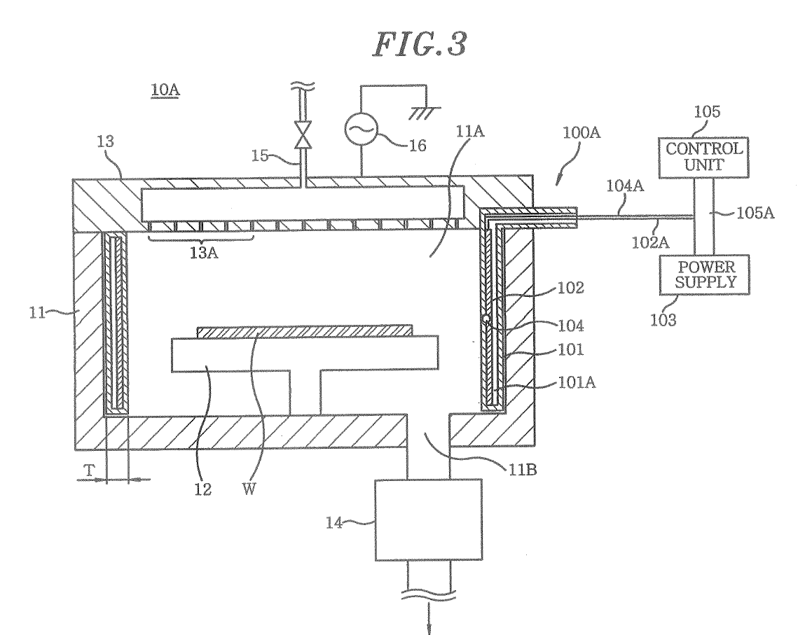

FIG. 3 shows a vacuum processing apparatus 10A which is a modified embodiment of the vacuum processing apparatus 10 shown in FIG. 1. Like parts are designated by like reference numerals in the drawings and redundant descriptions on the parts that have been described above will be omitted.

Referring to FIG. 3, the vacuum processing apparatus 10A of the present embodiment includes a shield member 100A that has a temperature measuring unit 104 for measuring a temperature of the outer wall structure 101 and a control unit 105 for controlling the heating unit 102 in response to the temperature measured by the temperature measuring unit 104.

The temperature measuring unit 104 includes, e.g., a thermocouple, and a signal corresponding to the temperature measured by the temperature measuring unit 104 is sent to the control unit 105 via the connecting line 104A. The control unit 105 controls the output of the power supply 103 in response to the temperature of the outer wall structure 101, thus controlling the heating unit 102.

In the shield member 100A of the present embodiment, the control unit 105 controls the output of the power supply 103 in response to the temperature measured by the temperature measuring unit 104 or the signal corresponding to the temperature. This makes it possible to control the shield member 101A to a desired temperature, which helps to stabilize the temperature of the shield member. This suppresses peeling-off of an attaching material from the shield member, thereby reducing generation of particles. Furthermore, it is possible to reduce the influence of temperature variation of the shield member on the substrate processing such as film formation, etching and surface treatment which makes the substrate processing stable.

The power supply and the control unit may be combined into a single unit that has a function of the power supply and a function of the control unit.

### Third Embodiment

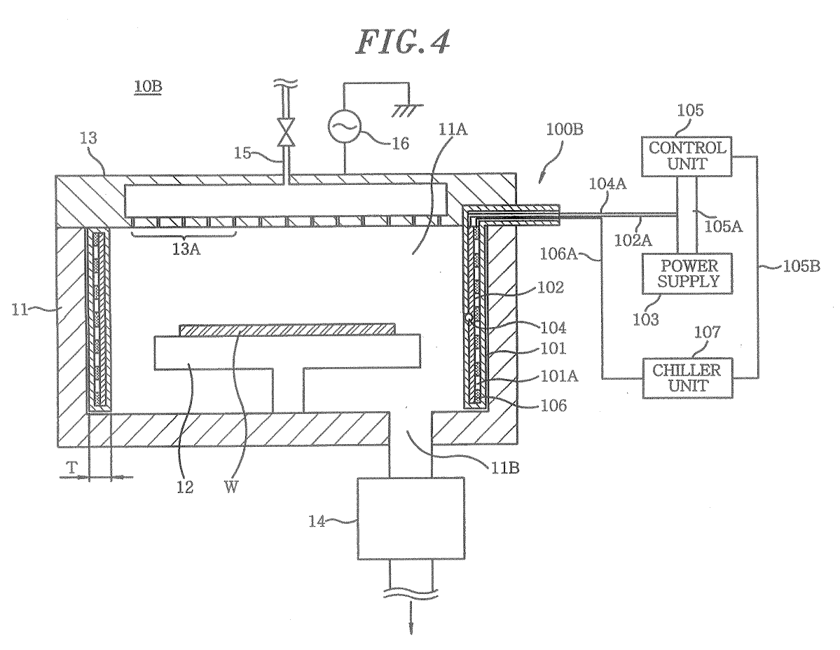

FIG. 4 shows a vacuum processing apparatus 10B which is modified from the vacuum processing apparatus 10A shown in FIG. 3. Like parts are designated by like reference numerals in the drawings and redundant descriptions on the parts that have been described above will be omitted.

Referring to FIG. 4, a shield member 100B is provided in the vacuum processing apparatus 10B of the present embodiment. Within the inner space 101A of the shield member 10B, there is provided a cooling unit 106 for cooling the outer wall structure 101.

The cooling unit 106 includes, e.g., a cooling pipe through which a coolant flows. By flowing the coolant, heat exchange occurs between the coolant and the outer wall structure 101 to thereby cool down the outer wall structure 101. In this case, it is possible to use as the coolant various mediums, e g., a liquid coolant such as cooling water, a gas coolant such as He, and the like.

The cooling unit 106 is connected to a chiller unit 107 through connecting lines 106A which includes e.g., a supply line for supplying the coolant from the chiller unit 107 to the cooling unit 106 and a recovery line for recovering the coolant from the cooling unit 106. The chiller unit 107 serves to cool down the coolant recovered from the cooling unit 106 and supply it to the cooling unit 106.

The control unit 105 controls the cooling power of the chiller unit 107 in response to the temperature measured by the temperature measuring unit 104 or the signal corresponding to the temperature. This makes it possible to control the shield member 100B to a desired temperature, which helps to stabilize the temperature of the shield member. Since the shield member 100B of the present embodiment has both the heating unit and the cooling unit, it becomes easy to stabilize the temperature of the outer wall structure 101 and to rapidly achieve a desired temperature, as compared with the case where the shield member has only the heating unit.

### Fourth Embodiment

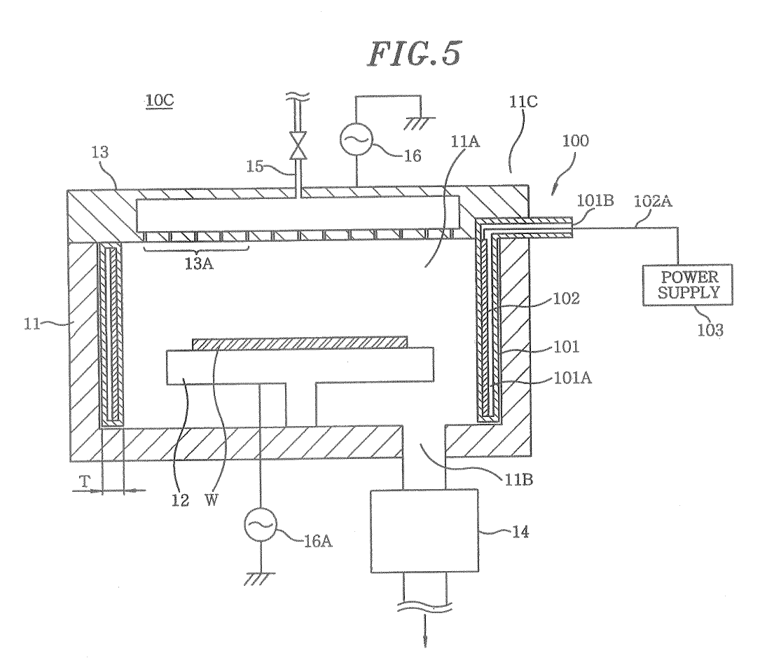

FIG. 5 shows a vacuum processing apparatus 10C which is another modified embodiment of the vacuum processing apparatus 10 shown in FIG. 1. Like parts are designated by like reference numerals in the drawings and redundant descriptions on the parts that have been described above will be omitted.

Referring to FIG. 5, the vacuum processing apparatus 10C includes a high frequency power supply 16A connected to the support base 12. This makes it possible to apply a high frequency power to the support base 12.

With such a configuration, the vacuum processing apparatus 10C of the present embodiment is capable of applying the high frequency power to both the supply section 13 and the support base 12. If necessary, the high frequency power may be applied to any one of the supply section 13 and the support base 12. Moreover, the frequencies of the high frequency powers applied to the supply section 13 and the support base 12 may be different from each other.

### Fifth Embodiment

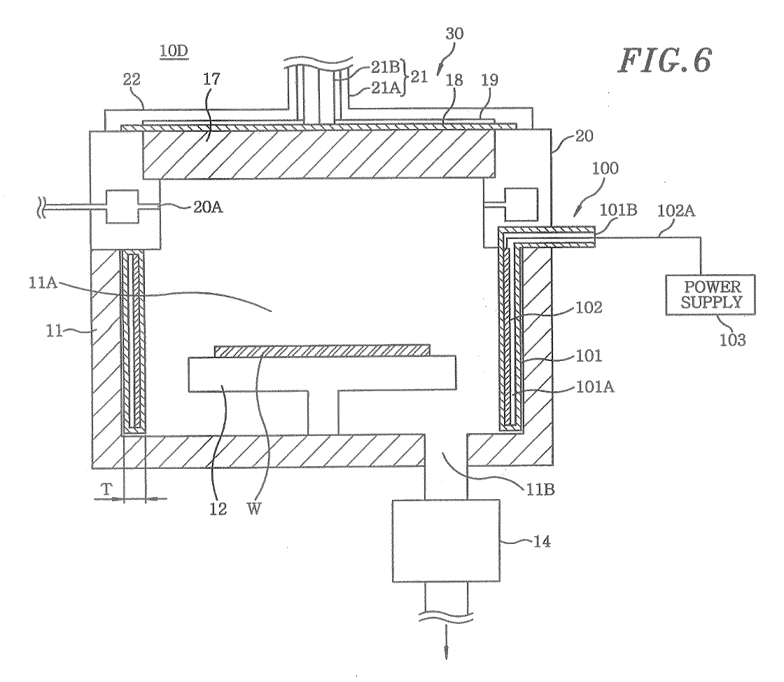

Next, FIG. 6 shows a vacuum processing apparatus 10D which is a still another modified embodiment of the vacuum processing apparatus 10 shown in FIG. 1. Like parts are designated by like reference numerals in the drawings and redundant descriptions on the parts that have been described above will be omitted.

Referring to FIG. 6, the vacuum processing apparatus 10D of the present embodiment includes a cover plate 17 made of a low-loss dielectric material and placed on the processing chamber 11 through a gas supply ring 20 in a position corresponding to the target substrate W on the support base 12. The cover plate 17 is disposed to face the target substrate W.

The cover plate 17 is seated on the gas supply ring 20 installed on the processing chamber 11. A ring-shaped plasma gas passage is formed in the gas supply ring 20 and is connected to a gas supply line for supplying a processing gas for use in a process such as film formation, etching, surface treatment or the like. A plural number of gas inlet holes 20A communicating with the plasma gas passage are formed in the gas supply ring 20 in a generally axial symmetry with respect to the target substrate W. The processing gas is supplied through the gas inlet holes 20A into the processing space 11A above the target substrate.

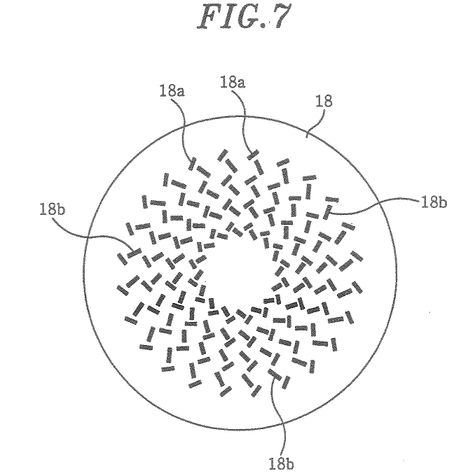

A radial line slot antenna 30 that has a radiation plate as shown in FIG. 7 is placed above the processing chamber 11 and the cover plate 17 with a gap of 4 to 5 mm left from the cover plate 17.

The radial line slot antenna 30 is seated on the gas supply ring 20 and is connected to an external microwave source (not shown) via a coaxial waveguide 21. The radial line slot antenna 30 radiates a microwave supplied from the microwave source toward the processing gas in the processing space 11A, thereby generating plasma.

The radial line slot antenna 30 includes a disc-shaped antenna main body 22 connected to an outer waveguide tube 21A of the coaxial waveguide 21 and a radiation plate 18 placed at the opening of the antenna main body 22. As shown in FIG. 7, a multiple number of mutually orthogonal slots 18a and 18b are formed in the radiation plate 18. A phase delay plate 19 formed of a dielectric plate having a uniform thickness is inserted between the antenna main body 22 and the radiation plate 18. Furthermore, a core conductor 21B constituting the coaxial waveguide 21 is connected to the radiation plate 18.

In the radial line slot antenna 30 configured as above, the microwave supplied through the coaxial waveguide 21 transmits forward while radially spreading between the disc-shaped antenna main body 22 and the radiation plate 18, at which time the wavelength of the microwave is shortened under the action of the phase delay plate 19. Accordingly, by forming the slots 18a and 18b in a concentric pattern and in a mutually orthogonal relationship to correspond to the wavelength of the radially transmitting microwave, it becomes possible to radiate a planar wave having a circularly polarized wave in a direction substantially perpendicular to the radiation plate 18.

Use of the radial line slot antenna 30 ensures that high density plasma is uniformly formed in the processing space 11A immediately below the cover plate 17. The high density plasma thus formed exhibits a low electron temperature, so that no damage is caused to the target substrate W. Moreover, since sputtering of the outer wall structure 101 of the shield member 100 is reduced, damage to the shield member is decreased.

Furthermore, the vacuum processing apparatus of the present embodiment shows enhanced uniformity in plasma density on the target substrate. Therefore, when using the shield member whose temperature influence on the target substrate is suppressed, the vacuum processing apparatus of the present embodiment has a feature of improving in-plane uniformity of the target substrate during the course of a substrate processing such as film formation, etching, surface treatment and the like.

As described above, the shield member of the present invention can be used in combination with a variety of vacuum processing apparatuses. The shield member is not limited to those of the foregoing embodiments but may be employed in various kinds of vacuum processing chambers.

### INDUSTRIAL APPLICABILITY

In accordance with the present invention, it becomes possible to provide a structurally simple and thin shield member employed in a processing chamber of a vacuum processing apparatus, the shield member having a heating unit, and a vacuum processing apparatus using the shield member.

What is claimed is:

1. A shield member provided in a processing chamber of a vacuum processing apparatus, the shield member comprising:
an outer wall structure exposed to a depressurized processing space in the processing chamber, the outer wall structure having an inner space isolated from the processing space; and
a heating unit provided within the inner space for heating the outer wall structure,
wherein the inner space communicates with an outside of the processing chamber and the heating unit is formed into a sheet shape to extend through the inner space.

2. The shield member of claim 1, wherein the outer wall structure including the inner space has a thickness of 5 mm or less.

3. The shield member of claim 1, further comprising a cooling unit for cooling down the outer wall structure provided within the inner space.

4. The shield member of claim 1 further comprising a temperature measuring unit for measuring a temperature of the outer wall structure and a control unit for controlling the heating unit in response to the temperature measured by the temperature measuring unit.

5. The shield member of claim 3, further comprising a temperature measuring unit for measuring a temperature of the outer wall structure and a control unit for controlling the heating unit and the cooling unit in response to the temperature measured by the temperature measuring unit.

6. A vacuum processing apparatus comprising
a gas exhaust unit for evacuating a processing space in a processing chamber;
a support base for supporting a target substrate; and
a shield member provided in the processing chamber, the shield member comprising:
an outer wall structure exposed to the processing space within the processing chamber, the outer wall structure having an inner space isolated from the processing space; and
a heating unit provided within the inner space for heating the outer wall structure,
wherein the inner space communicates with an outside of the processing chamber and the heating unit is formed into a sheet shape to extend through the inner space.

7. The vacuum processing apparatus of claim 6, wherein the outer wall structure including the heating unit has a thickness of 5 mm or less.

8. The vacuum processing apparatus of claim 6, wherein the shield member further comprises a cooling unit for cooling down the outer wall structure provided within the inner space.

9. The vacuum processing apparatus of claim 6, further comprising a temperature measuring unit for measuring a temperature of the outer wall structure and a control unit for controlling the heating unit in response to the temperature measured by the temperature measuring unit.

10. The vacuum processing apparatus of claim 8, further comprising a temperature measuring unit for measuring a temperature of the outer wall structure and a control unit for controlling the heating unit and the cooling unit in response to the temperature measured by the temperature measuring unit.

11. The vacuum processing apparatus of claim 6, wherein the shield member is formed along an inner wall surface of the processing chamber to surround the support base.

12. The vacuum processing apparatus of claim 6, wherein the shield member has a generally cylindrical shape.

13. The vacuum processing apparatus of claim 6, wherein a capacitively coupled plasma generating unit is provided in the processing chamber.

14. The vacuum processing apparatus of claim 6 wherein a plasma generating unit including a radial line slot antenna is provided in the processing chamber.
